(19) United States
(12) Patent Application Publication
(10) Pub. No.: US 2025/0383404 A1
(43) Pub. Date: Dec. 18, 2025

(54) METHODS OF INDICATING BATTERY CAPACITY

(71) Applicant: Schlumberger Technology Corporation, Sugar Land, TX (US)

(72) Inventors: Gema Cabello Carramolino, Cambridge (GB); Javier Rubio Garcia, Cambridge (GB); Debora Campos de Faria, Cambridge (GB)

(21) Appl. No.: 19/093,797

(22) Filed: Mar. 28, 2025

Related U.S. Application Data
(60) Provisional application No. 63/660,610, filed on Jun. 17, 2024.

(51) Int. Cl. G01R 31/382; H01M 10/44; H01M 10/48

(52) U.S. Cl. CPC G01R 31/382; H01M 10/44; H01M 10/48

(57) ABSTRACT

The present disclosure provides apparatuses and methods of performing controlling actions. The method includes charging a battery having a cathode. The cathode includes a redox indicator. The battery is discharged, where discharging the battery includes identifying a potential drop of the redox indicator. The controlling action is performed based on the potential drop.

### CROSS REFERENCE TO RELATED APPLICATIONS

The present disclosure claims priority from U.S. Provisional Appl. No. 63/660610, filed on June 17, 2024, herein incorporated by reference in its entirety.

### BACKGROUND

Rechargeable batteries have been implemented for large-scale energy storage as well as in electric vehicles because the rechargeable batteries include a high capacity and have highly reliable components. Rechargeable batteries may undergo cycles of charging and discharging, in which the state of charge of the battery is critical to determine where in the cycle the stored energy currently resides. Estimations to determine the battery state of charge may prevent overcharge or full discharge, improve battery life, and indicate the battery performance overall. The battery state of charge is quantified by determining the ratio of residual capacity and the overall battery capacity, where the measurement of residual capacity is influenced by several factors such as charge/discharge rate, temperature, self-discharge, cycle life, fading capacity, aging effects, and net discharge volume.

Current state of charge estimation methods, e.g., coulomb counting, open circuit potential, discharge experiment method, and metrology, may implement one or more of these factors to determine the state of charge of the battery. Unfortunately, each of the estimation methods includes one or more estimations and/or are time consuming, limiting their overall use for measurements. For example, the Coulomb counting method fails to accurately estimate the initial state of charge of the battery. Moreover, the open circuit voltage method requires the battery to be idle for more than 10 hours prior to making a measurement, which makes the method impractical for a battery in active duty.

Accordingly, an improved method of monitoring the state of charge of a battery is needed.

### SUMMARY

The present disclosure provides apparatuses. The apparatuses includes a cathode. The cathodes include a redox indicator. The redox indicator is selected from the group consisting of an organic compound, an organometallic compound, and a transition metal oxide. The apparatus includes an anode.

The present disclosure provides methods of performing controlling actions. The method includes charging a battery having a cathode. The cathode includes a redox indicator. The battery is discharged, where discharging the battery includes identifying a potential drop of the redox indicator. The controlling action is performed based on the potential drop.

The present disclosure also provides methods of forming an electrode. The methods include producing a cathode by disposing a redox indicator in a cathode using a co-deposition synthesis reaction. The redox indicator is selected from the group consisting of an organic compound, an organometallic compound, and a transition metal oxide.

The following description and the appended figures set forth certain features for purposes of illustration.

### BRIEF DESCRIPTION OF DRAWINGS

So that the manner where the above recited features may be understood in detail, a more particular description, briefly summarized above, may be had by reference to example aspects, some of which are illustrated in the appended drawings.

FIGS. 1A-1C depict a schematic of a battery, according to embodiments of the present disclosure.

FIGS. 2A-2D depict a schematic of a redox indicator disposed on or in a plurality of atomic sheets of a semi-conductive component, according to embodiments of the present disclosure.

FIG. 3 depicts a workflow of a method of forming a cathode having a redox indicator, according to embodiments of the present disclosure.

FIG. 4 depicts a workflow of a method of performing a controlling action based on a cathode having a redox indicator, according to embodiments of the present disclosure.

FIG. 5 depicts a graphical illustration of voltage vs. current of a cathode having a redox indicator, according to embodiments of the present disclosure.

### DETAILED DESCRIPTION

One or more specific embodiments of the present disclosure will be described herein. These described embodiments are only examples of the presently disclosed techniques. Additionally, in an effort to provide a concise description of these embodiments, all features of an actual implementation may not be described in the specification. It should be appreciated that in the development of any such actual implementation, as in any engineering or design project, numerous implementation-specific decisions are made to achieve the developers’ specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

The present disclosure relates to apparatuses and methods of monitoring a battery state of charge using a redox indicator. A redox indicator permits a state of charge to be determined by implementing a second drop in potential within the discharge profile. The second drop in potential may indicate one or more remaining capacities of the battery, e.g., about 1% to about 20% of remaining capacity of charge in the battery, such as about 1% to about 5%, about 3% to about 8%, about 5% to about 10%, about 7% to about 12%, about 9% to about 14%, about 11% to about 16%, about 13% to about 18%, or about 15% to about 20%. The redox indicator may also allow for enhanced electron transfer capacity of the battery due to the strong electron interaction and synergistic effects of the redox indicator with the cathode of the battery.

The present disclosure may include a battery. The battery can include one or more of an aluminum ion battery, calcium battery, vanadium redox battery, zinc-bromine battery, zinc-cerium battery, hydrogen-bromine battery, lead-acid battery, magnesium ion battery, germanium-air battery, calcium-air battery, iron-air battery, potassium-ion battery, silicon-air battery, zinc-air battery, tin-air battery, sodium-air battery, beryllium-air battery, nickel-cadmium battery, nickel-iron battery, nickel-lithium battery, metal hydrogen battery, such as a nickel-metal hydride battery, nickel zinc battery, polymer-based battery, polysulfide-bromide battery, potassium-ion battery, silver-zinc battery, silver-cadmium battery, silver-calcium battery, sodium-ion battery, sodium-sulfur battery, or zinc-ion battery. In one embodiment, the battery includes a metal-hydrogen battery.

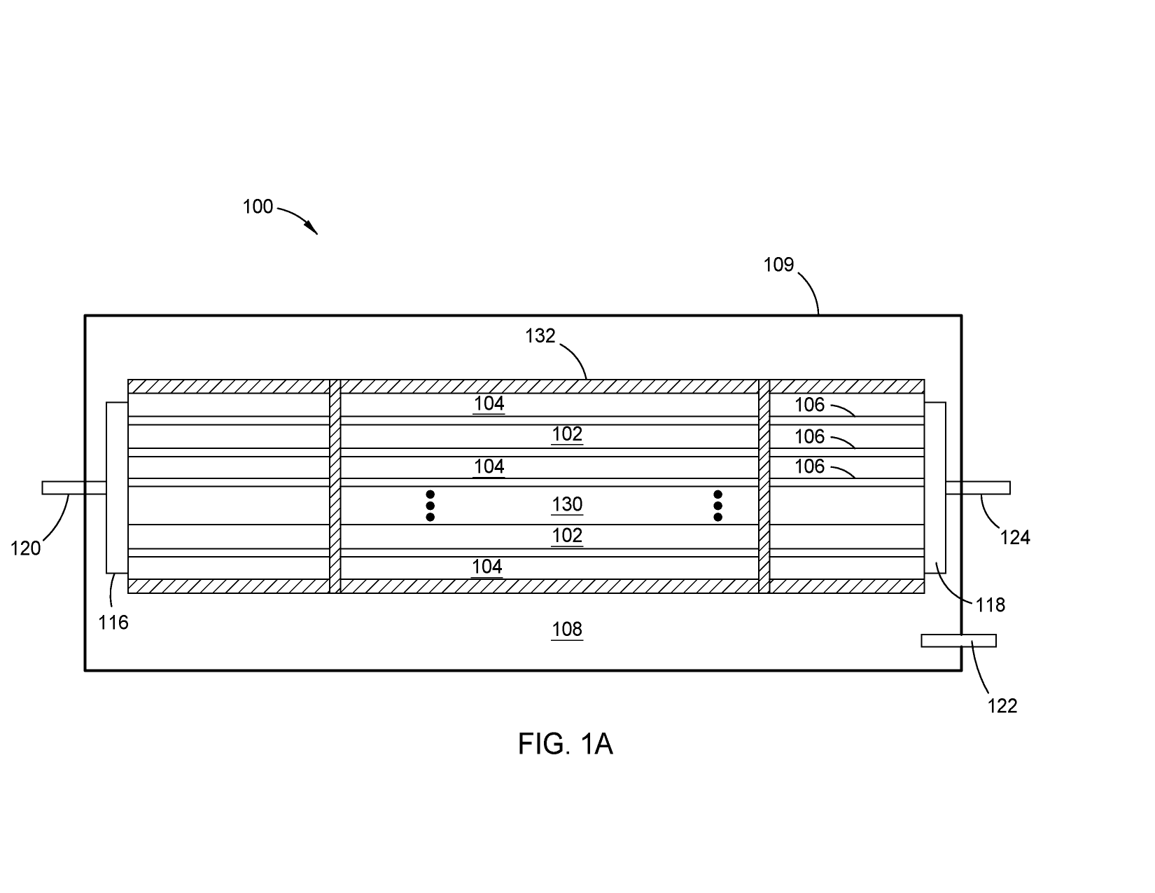

Now referring to FIG. 1A, a schematic depiction of a metal-hydrogen battery 100 is depicted. The metal-hydrogen battery 100 includes an electrode stack assembly 130 that includes stacked electrodes that are separated by separators 106. The electrode stack assembly 130 includes alternately stacked cathode electrodes 102 and anode electrodes 104 as illustrated in FIG. 1A. The cathode electrodes 102 and the anode electrodes 104 are separated by separators 106 that are disposed between them. The separator 106 can be saturated with an electrolyte 108. In some embodiments, the separator 106 also provides a reservoir of electrolyte 108 that buffers the electrodes from either drying out or flooding during operation of the battery 100. In some embodiments, the electrolyte 108 is an aqueous electrolyte. The aqueous electrolyte is alkaline and has a pH greater than 7, such as about 7.5 or greater, about 8 or greater, about 8.5 or greater, or about 9 or greater, or about 11 or greater, or about 13 or greater. As a non-limiting example, the electrolyte 108 may include KOH or NaOH or Li OH or a mixture of LiOH, NaOH and/or KOH.

The electrode stack assembly 130 can be housed in a pressure vessel 109. As illustrated, an electrolyte 108 is disposed in the pressure vessel 109 such that the stack 130 is saturated with the electrolyte 108. The cathode electrode 102, the anode electrode 104, and the separator 106 are porous to hold the electrolyte 108 and allow ions in the electrolyte 108 to transport between the cathode electrodes 102 and the anode electrodes 104. In some embodiments, the separator 106 can be omitted as long as the cathode electrodes 102 and the anode electrodes 104 can be electrically insulated from each other and the electrolyte 108 can be held in the electrode stack 130. For example, the space occupied by the separator 106 may be filled with the electrolyte 108.

The metal-hydrogen battery 100 can include a fill tube 122 configured to introduce electrolyte or gasses (e.g. hydrogen) into the pressure vessel 109. The fill tube 122 may include one or more valves (not shown) to control flow into and out of the enclosure of the pressure vessel 109 or the fill tube 122 may be otherwise sealable after charging the pressure vessel 109 with the electrolyte 108 and the hydrogen gas. Although FIG. 1A illustrates that the fill tube 122 is positioned on the side of the conductor 118, the fill tube 122 may alternatively be placed on the side of the conductor 116, or otherwise placed anywhere on the pressure vessel.

The electrode stack assembly 130 can include a number of stacked layers of alternating cathode electrodes 102 and anode electrodes 104 separated by separators 106. Although shown as being coupled in parallel in FIG. 1A, the electrodes in the electrode stack assembly 130 may be coupled either in parallel or in series. In particular, each of the cathode electrodes 102 are coupled to the conductor 118 and each of the anode electrodes 104 are coupled to the conductor 116. The electrode stack assembly 130 can be positioned in the pressure vessel 109 and contain the electrolyte 108, where ions in the electrolyte 108 can transport between cathode electrodes 102 and anode electrodes 104. The separator 106 can be a porous insulator. In some embodiments, the electrolyte 108 is an aqueous electrolyte that is alkaline (with a pH greater than 7).

The conductor 116, which is coupled to the anode electrodes 104, is electrically coupled to a terminal 120, which may present one terminal of battery 100. The terminal 120 can include a feedthrough to allow the terminal 120 to extend outside of the pressure vessel, or the conductor 116 may be connected directly to the pressure vessel 109 because the terminal 120 is coupled to the anode electrodes 104. Similarly, the conductor 118, which is coupled to the cathode electrodes 102, can be coupled to a terminal 124 that represents the opposite (positive) terminal of the battery 100. The terminal 124 can also pass through an insulated feedthrough to allow the terminal 124 to extend to the outside of the pressure vessel 109 because the terminal 124 is coupled to the cathode electrodes 102.

The electrode stack can be fixed within a frame 132. For example, the electrode stack assembly 130 can be organized with the anode electrodes 104 on both sides adjacent to the frame 132, in order to isolate the cathode electrodes 102 from the frame 132. In some embodiments, a separator 106 can be included adjacent to the frame 132 for further isolation, such as where the electrode stack assembly 130 is arranged such that the cathode electrodes 102 are adjacent to the frame 132 rather than the anode electrodes 104.

FIG. 1B illustrates a cathode electrode. The cathode electrode 102 can include one or more cathode porous layers 140, each of the porous layers 140 formed of a conductive substrate 114 covered with a coating. The coating can be a redox-reactive material that includes a transition metal, as is discussed further below. Alternatively, the cathode electrode 102 can include one or more atomic sheets (not shown) that are disposed on top of one another such that a layering of the atomic sheets (not shown) occurs. The atomic sheets may include an atomic sheet of one or more of a semi-conductive or a conductive component. For example, the atomic sheets may include a semi-conductive component such as nickel oxyhydroxide or nickel hydroxide. Alternatively, the atomic sheet may include a conductive component such as molybdenum disulfide. In an embodiment, the atomic sheets may be a redox-reactive material that includes a transition metal, e.g., nickel, silver, cobalt, molybdenum, or manganese. In some embodiments, the transition metal can be cobalt. In some embodiments, cobalt is included as cobalt oxide or zinc cobalt oxide. In some embodiments, the transition metal can be manganese. In some embodiments, manganese can be included as manganese oxide or doped manganese oxide (e.g., doped with nickel, copper, bismuth, yttrium, cobalt or other transition or post-transition metals). Other transition metals are encompassed by this disclosure, such as silver. In some embodiments, the one or more atomic sheets may layer to produce a total thickness of about 1 μm to about 100 μm, about 1 μm to about 50 μm, or about 1 μm to about 10 μm.

In an embodiment, the atomic sheets (not shown) may include atomic sheets of nickel hydroxide or nickel oxyhydroxide. The atomic sheets (not shown) may be in a charged state or a discharged state. For example, where the atomic sheets (not shown) are nickel hydroxide, the nickel hydroxide may exist in a discharged state such as β(II)-nickel hydroxide or α-nickel hydroxide. Alternatively, where the atomic sheets (not shown) are nickel oxyhydroxide, the nickel oxyhydroxide may exist in a charged state such as β(III-IV)-nickel oxyhydroxide or γ-nickel oxyhydroxide. The atomic sheets (not shown) may be in an overcharged state where the β(III-IV)-nickel oxyhydroxide is converted to γ-nickel oxyhydroxide, which has a higher average valence state compared to β(III-IV)-nickel oxyhydroxide.

Each sheet of the plurality of atomic sheets may be separated by a distance of about 1 Å to about 10 Å, e.g., about 1 Å to about 2 Å, about 2 Å to about 3 Å, about 3 Å to about 4 Å, about 4 Å to about 5 Å, about 5 Å to about 6 Å, about 6 Å to about 7 Å, about 7 Å to about 8 Å, about 8 Å to about 9 Å, or about 9 Å to about 10 Å, between each atomic sheet of the plurality of atomic sheets. For example, where the atomic sheets include atomic sheets of β(II)-nickel hydroxide the distance between each atomic sheet of the atomic sheets may be about 4.5 Å to about 4.7 Å, e.g., about 4.5 Å to about 4.55 Å, about 4.55 Å to about 4.60 Å, about 4.60 Å to about 4.65 Å, or about 4.65 Å to about 4.70 Å. As a further example, where the atomic sheets include atomic sheets of β(III)-nickel oxyhydroxide the distance between each atomic sheet of the atomic sheets may be about 4.7 Å to about 4.9 Å, e.g., about 4.7 Å to about 4.75 Å, about 4.75 Å to about 4.80 Å, about 4.80 Å to about 4.85 Å, or about 4.85 Å to about 4.90 Å. As a further example, where the atomic sheets include atomic sheets of γ-nickel oxyhydroxide the distance between each atomic sheet of the atomic sheets may be about 7 Å to about 8 Å, e.g., about 7.1 Å to about 7.2 Å, about 7.2 Å to about 7.3 Å, about 7.3 Å to about 7.4 Å, about 7.4 Å to about 7.5 Å, about 7.5 Å to about 7.6 Å, about 7.6 Å to about 7.7 Å, about 7.7 Å to about 7.8 Å, about 7.8 Å to about 7.9 Å, about 7.9 Å to about 8.0 Å. As a further example, where the atomic sheets include atomic sheets of α-nickel hydroxide the distance between each atomic sheet of the atomic sheets may be about 8 Å to about 9 Å, e.g., about 8.1 Å to about 8.2 Å, about 8.2 Å to about 8.3 Å, about 8.3 Å to about 8.4 Å, about 8.4 Å to about 8.5 Å, about 8.5 Å to about 8.6 Å, about 8.6 Å to about 8.7 Å, about 8.7 Å to about 8.8 Å, about 8.8 Å to about 8.9 Å, about 8.9 Å to about 9.0 Å. Without being bound by theory, by layering each atomic sheet of the plurality of atomic sheets such that each layer is separated by a distance, the surface area of the cathode may be increased such that a diffusion distance of protons is reduced during charging and/or discharging. By reducing the diffusion distance of protons an increase in the power output occurs as protons may be exchanged faster.

The plurality of atomic sheets (not shown) may coat and/or cover a conductive substrate 114. In some embodiments, the conductive substrate 114 is porous, such as having a porosity of at least about 10%, at least about 20%, at least about 30%, at least about 40%, or at least about 50%, and up to about 80%, up to about 90%, or greater. In some embodiments, the conductive substrate 114 can be formed of a metal foam, such as a nickel foam, or a metal alloy foam. Other conductive substrates are encompassed by this disclosure, such as metal foils, metal meshes, and fibrous conductive substrates. In an embodiment, the conductive substrate 114 may be a nickel mesh. In some embodiments, the conductive substrate 114 can be formed of carbon-based materials, such as carbon fibrous paper, carbon cloth, carbon felt, carbon mat, carbon nanotube film, graphite foil, graphite foam, graphite mat, graphene foil, graphene fibers, graphene film, and graphene foam.

In an embodiment, a redox indicator may be disposed on or in the cathode 102. The redox indicator may include an organometallic compound. An organometallic compound includes a compound having at least one chemical bond between a carbon atom of an organic molecule and a metal atom, such as an alkali metal, alkaline earth metal, metalloid, actinide, lanthanide, semimetal, and/or transition metal. An organometallic compound may include one or more compounds having a bond to a carbon monoxide, cyanide, or carbide group. For example, an organometallic compound may include a transition metal hydride and/or a metal phosphine complex. As a further example, metal β-diketonates, alkaloids, or dialkylamides may be an organometallic compound. In an embodiment, an organometallic compound may include one or more of ferrocene, cobaltocene, tri(triphenylphosphine)rhodium carbonyl hydride, Zeise’s salt, trimethylaluminum, dimethylzinc, lithium diphenylcuprate bi(diethyl ethereate), adenosylcobalamin, iron pentacarbonyl, trimethylboron, trimethyl silicon, thianthrene, iron(II) tris-bipyridine, decamethylferrocene, oxaphosphirane complexes, ferrocenium salts, silver(I) salts, copper(II) halide, copper(I) salts, trications, benzoquinone derivatives and polymers, (poly)(2,2,6,6-Tetramethylpiperidin-1-yl)oxyl “(poly)TEMPO”, and/or technetium sestamibi. In an embodiment, the organometallic compound may be ferrocene, ferrocenium, and/or a ferrocene derivative. In an embodiment, the organometallic compound may be a compound that has a strong electron interaction and/or synergistic effects with the semi-conductive component, e.g., the nickel of nickel hydroxide or nickel oxyhydroxide.

In an embodiment, the redox marker may include a transition metal oxide. A transition metal oxide is a compound that is composed of oxygen atoms bound to one or more transition metals, such as group 3 transition metals, group 4 transition metals, group 5 transition metals, group 6 transition metals, group 7 transition metals, group 8 transition metals, group 9 transition metals, group 10 transition metals, group 11 transition metals, and/or group 12 transition metals. Additionally, a transition metal oxide may include a compound that is composed of oxygen atoms bound to one or more actinides or lanthanides. For example, a transition metal oxide may include Fe₂O₃, CuO, ZnO, and/or MnO₂. In an embodiment, the transition metal oxide may be a compound that has a strong electron interaction and/or synergistic effects with the semi-conductive component, e.g., the nickel of nickel hydroxide or nickel oxyhydroxide.

The redox marker may include an organic compound. An organic compound includes a compound comprising carbon-hydrogen and/or carbon-carbon bonds. In an embodiment, an organic compound can include a compound comprising one or more atoms selected from the group of carbon, oxygen, nitrogen, hydrogen, or halides. An organic compound can include graphene, allotropes of carbon, or polymers. In an embodiment, an organic compound can include quinones, e.g., benzoquinone, napthoquinone, anthraquinone, chloranil, lawsome, alizarin, daunorubicin, or 2,3-dichloro-5,6-dicyano-1,4-benzoquinone. In an embodiment, the organometallic compound may be a compound having resonance, which may lead to a strong electron interaction and/or synergistic effects with the semi-conductive component, e.g., the nickel of nickel hydroxide or nickel oxyhydroxide.

In an embodiment, the redox marker includes a reversible redox behavior having a redox potential within the operating potential of the battery. For example, a redox marker can include a reversible redox behavior having a redox potential of about 0.1 V to about 1.5 V as measured by a reversible hydrogen electrode (RHE), e.g., about 0.1 V to about 0.5 V, about 0.3 V to about 0.7 V, about 0.5 V to about 0.9 V, about 0.7 V to about 0.9 V, about 0.8 V to about 1.0V, about 0.9 V to about 1.1 V, about 1.0 V to about 1.2 V, about 1.1 V to about 1.3 V, about 1.2 V to about 1.4 V, about 1.3 V to about 1.5 V. In an embodiment the redox marker includes a reversible redox behavior having a redox potential of about less than 1.4 V, as measured by RHE. Without being bound by theory, a redox marker having a redox potential below 1.4 V may provide a potential drop within a discharge profile of the battery such that a state of charge may be indicated based on the location of the redox marker within the battery.

In an embodiment, the cathode electrode 102 may include a porous substrate with a catalyst. The catalyst can include a bi-functional catalyst to catalyze both hydrogen evolution reaction (HER) and hydrogen oxidation reaction (HOR) at the cathode electrode 102. In some embodiments, the porous substrate has a porosity of at least about 10%, at least about 20%, at least about 30%, at least about 40%, or at least about 50%, and up to about 80%, up to about 90%, 95% or greater. In some embodiments, the porous substrate can be a metal foam, such as a nickel foam, an iron foam, a copper foam, a steel foam, or others. In some embodiments, the porous substrate is metal alloy foam, such as a nickel-molybdenum foam, a nickel-iron foam, a nickel-copper foam, a nickel-cobalt foam, a nickel-tungsten foam, a nickel-silver foam, a nickel-molybdenum-cobalt foam, or others. The porous substrate can be formed of other conductive substrates, for example, metal foils, metal meshes, and fibrous conductive substrates. In some embodiments, the porous substrate can be formed of carbon-based materials, such as carbon fibrous paper, carbon cloth, carbon felt, carbon mat, carbon nanotube film, graphite foil, graphite foam, graphite mat, graphene foil, graphene fibers, graphene film, and graphene foam.

In some embodiments, the bi-functional catalyst can be a nickel-molybdenum-cobalt (NiMoCo) alloy. Other transition metal or metal alloys can be bi-functional catalysts, for example, nickel, nickel-molybdenum, nickel-tungsten, nickel tungsten-cobalt, nickel-tungsten-copper, nickel-carbon, nickel-chromium based composites. In some embodiments, bi-functional catalyst can include a transition metal alloy that includes two or more of Ni, Co, Cr, Mo, Fe, Mn, Cu, Zn, Sn, and W. Other precious metals and their alloys can also be included in bi-functional catalysts, for example, platinum, palladium, iridium, gold, rhodium, ruthenium, rhenium, osmium, silver, and their alloys with precious and non-precious transition metals such as platinum, palladium, iridium, gold, rhodium, ruthenium, rhenium, osmium, silver, nickel, cobalt, manganese, iron, molybdenum, tungsten, chromium and so forth. In some embodiments, bifunctional catalysts can be a combination of HER and HOR catalysts. In some embodiments, the bi-functional catalysts can include a mixture of different materials, such as transition metals and their oxides/hydroxides, which contribute to hydrogen evolution and oxidation reactions as a whole. In some embodiments, the catalyst is a nanostructure of a bi-functional catalyst having sizes (or an average size) in a range of, for example, about 1 nm to about 100 nm, about 1 nm to about 80 nm, or about 1 nm to about 50 nm. In some embodiments, the catalyst layer 112 includes microstructures of the bi-functional catalyst having sizes (or an average size) in a range of, for example, about 100 nm to about 500 nm, about 500 nm to about 1000 nm.

In an embodiment, where the cathode includes a porous substrate encapsulated by a catalyst, a redox marker may be disposed on or in the porous substrate. The redox marker may include any of the redox markers described herein. For example, the redox marker may include an organometallic compound which may be ferrocene, ferrocenium, and/or a ferrocene derivative. Alternatively, the redox marker of a cathode including a porous substrate encapsulated by a catalyst may be a transition metal oxide such as Fe, Mn, V, Mo, Ag, W, Zn, and/or metallocenes. In an embodiment, the redox marker includes a reversible redox behavior having a redox potential of about 0.1 V to about 1.5 V as measured by a reversible hydrogen electrode (RHE), e.g., about less than 1.4 V, as measured by RHE. Without being bound by theory, a redox marker having a redox potential below 1.4 V may provide a potential drop within a discharge profile of the battery such that a state of charge may be indicated based on the location of the redox marker within the battery.

In some embodiments, the anode electrode 104 may be a single-layer structure or a multilayer structure. In some embodiments, the anode electrode 104 can be formed with a flat or with uneven surfaces. In some embodiments, multiple layers can be formed with a combination of flat and uneven surfaces. In some embodiments, the anode electrode 104 is a catalytic hydrogen electrode.

As illustrated in FIG. 1C, the anode electrode 104 can include one or more anode porous layers 142, each of the anode porous layers 142 include a porous conductive substrate 110 coated with a catalyst layer 112. The catalyst layer 112 can include a bi-functional catalyst to catalyze both hydrogen evolution reaction (HER) and hydrogen oxidation reaction (HOR) at the anode electrode 104. In some embodiments, the porous conductive substrate 110 has a porosity of at least about 10%, at least about 20%, at least about 30%, at least about 40%, or at least about 50%, and up to about 80%, up to about 90%, 95% or greater. In some embodiments, the porous conductive substrate 110 can be a metal foam, such as a nickel foam, an iron foam, a copper foam, a steel foam, or others. In some embodiments, the porous conductive substrate 110 is metal alloy foam, such as a nickel-molybdenum foam, a nickel-iron foam, a nickel-copper foam, a nickel-cobalt foam, a nickel-tungsten foam, a nickel-silver foam, a nickel-molybdenum-cobalt foam, or others. Porous conductive substrate 110 can be formed of other conductive substrates, for example, metal foils, metal meshes, and fibrous conductive substrates. In some embodiments, the conductive substrate 110 can be formed of carbon-based materials, such as carbon fibrous paper, carbon cloth, carbon felt, carbon mat, carbon nanotube film, graphite foil, graphite foam, graphite mat, graphene foil, graphene fibers, graphene film, and graphene foam.

In some embodiments, the bi-functional catalyst of the catalyst layer 112 can be a nickel-molybdenum-cobalt (NiMoCo) alloy. Other transition metal or metal alloys can be bi-functional catalysts, for example, nickel, nickel-molybdenum, nickel-tungsten, nickel tungsten-cobalt, nickel-tungsten-copper, nickel-carbon, nickel-chromium, based composites. In some embodiments, bi-functional catalyst of catalyst layer 112 can include a transition metal alloy that includes two or more of Ni, Co, Cr, Mo, Fe, Mn, Cu, Zn, Sn, and W. Other precious metals and their alloys can also be included in bi-functional catalysts, for example, platinum, palladium, iridium, gold, rhodium, ruthenium, rhenium, osmium, silver, and their alloys with precious and non-precious transition metals such as platinum, palladium, iridium, gold, rhodium, ruthenium, rhenium, osmium, silver, nickel, cobalt, manganese, iron, molybdenum, tungsten, chromium and so forth. In some embodiments, bifunctional catalysts of catalyst layer 112 can be a combination of HER and HOR catalysts. In some embodiments, the bi-functional catalysts of catalyst layer 112 can include a mixture of different materials, such as transition metals and their oxides/hydroxides, which contribute to hydrogen evolution and oxidation reactions as a whole. In some embodiments, the catalyst layer 112 includes nanostructures of the bi-functional catalyst having sizes (or an average size) in a range of, for example, about 1 nm to about 100 nm, about 1 nm to about 80 nm, or about 1 nm to about 50 nm. In some embodiments, the catalyst layer 112 includes microstructures of the bi-functional catalyst having sizes (or an average size) in a range of, for example, about 100 nm to about 500 nm, about 500 nm to about 1000 nm.

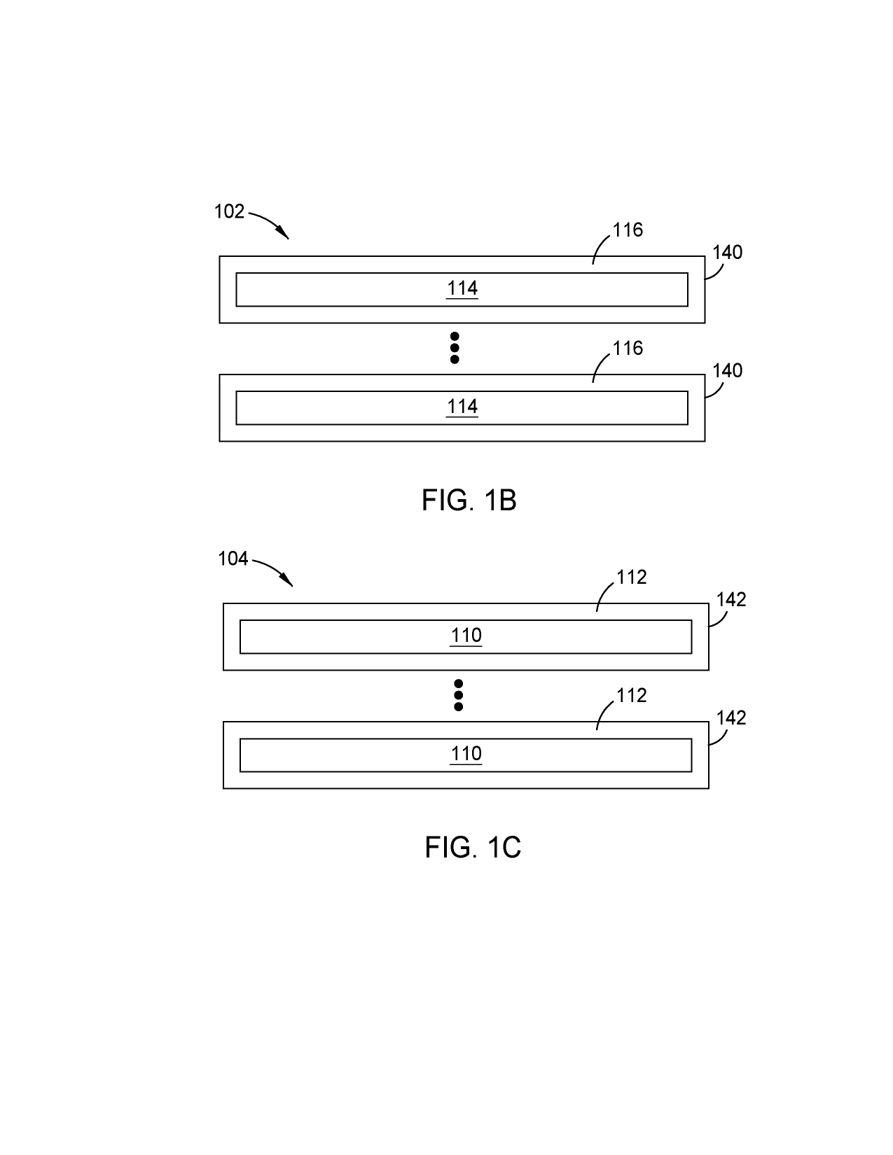

Now referring to FIGS. 2A-2D, an embodiment of a cathode 102 including a plurality of atomic sheets of a semi-conductive component having a redox indicator located above a first atomic layer as shown. The plurality of atomic sheets can include a first layer 201 of a semi-conductive component. The first layer 201 of a semi-conductive component can include a redox-reactive material that includes a transition metal, e.g., nickel, silver, cobalt, or manganese. In some embodiments, the transition metal can be cobalt. In some embodiments, cobalt is included as cobalt oxide or zinc cobalt oxide. In some embodiments, the transition metal can be manganese. In some embodiments, manganese can be included as manganese oxide or doped manganese oxide (e.g., doped with nickel, copper, bismuth, yttrium, cobalt or other transition or post-transition metals). Other transition metals are encompassed by this disclosure, such as silver. In an embodiment, the first layer 201 can include nickel hydroxide or nickel oxyhydroxide.

The plurality of atomic sheets can include a second layer 202 of the semi-conductive component. The second layer 202 of the semi-conductive component can include a redox-reactive material that includes a transition metal, e.g., nickel, silver, cobalt, or manganese. In some embodiments, the transition metal can be cobalt. In some embodiments, cobalt is included as cobalt oxide or zinc cobalt oxide. In some embodiments, the transition metal can be manganese. In some embodiments, manganese can be included as manganese oxide or doped manganese oxide (e.g., doped with nickel, copper, bismuth, yttrium, cobalt or other transition or post-transition metals). Other transition metals are encompassed by this disclosure, such as silver. In an embodiment, the second layer 202 can include nickel hydroxide or nickel oxyhydroxide. The first layer 201 and the second layer 202 can be or have the same semi-conductive component, redox-reactive material, or transition metal.

The plurality of atomic sheets can include a third layer 203 of the semi-conductive component. The third layer 203 of the semi-conductive component can include a redox-reactive material that includes a transition metal, e.g., nickel, silver, cobalt, or manganese. In some embodiments, the transition metal can be cobalt. In some embodiments, cobalt is included as cobalt oxide or zinc cobalt oxide. In some embodiments, the transition metal can be manganese. In some embodiments, manganese can be included as manganese oxide or doped manganese oxide (e.g., doped with nickel, copper, bismuth, yttrium, cobalt or other transition or post-transition metals). Other transition metals are encompassed by this disclosure, such as silver. In an embodiment, the third layer 203 can include nickel hydroxide or nickel oxyhydroxide. The first layer 201, the second layer 202, and the third layer 203 can be or have the same semi-conductive component, redox-reactive material, or transition metal.

Each of the first layer 201, second layer 202, and third layer 203 are separated by a distance. The first layer 201 may be separated from the second layer 202 by a distance “d¹”, where d¹ may range from about 1 Å to about 4 Å, e.g., about 1 Å to about 2 Å, about 2 Å to about 3 Å, or about 3 Å to about 4 Å. The second layer 202 may be separated from the third layer 203 by a distance “d²”, where d² may range from about 1 Å to about 4 Å, e.g., about 1 Å to about 2 Å, about 2 Å to about 3 Å, or about 3 Å to about 4 Å. In an embodiment, d¹ and d² are not the same. For example, the d¹ may be about 3.5 Å while d² may be about 4.0 Å. In an embodiment, d¹ and d² are the same. For example, d¹ and d² may both be about 3.5 Å. Without being bound by theory, by separating the first layer 201, second layer 202, and third layer 203, the surface area of the cathode may be increased such that a diffusion distance of protons is reduced during charging and/or discharging. By reducing the diffusion distance of protons an increase in the power output occurs as protons may be exchanged faster. In an embodiment, d¹ and d² may combine to provide a total thickness of the plurality of atomic sheets. The total thickness of the plurality of atomic sheets may be from about 1 μm to about 100 μm, about 1 μm to about 50 μm, or about 1 μm to about 10 μm.

A redox indicator 204 may be disposed on a top surface of the first atomic layer 201, where the top surface of the redox indicator 204 is the surface opposite a bottom surface of the first atomic layer 201. The bottom surface of the first atomic layer 201 is disposed adjacent to a top surface of a second layer 202 of the semi-conductive component of the plurality of atomic sheets, as shown in FIG. 2A. Without being bound by theory a redox indicator 204 disposed on a top surface of the first atomic layer 201 may indicate that the battery has about 20% to about 25% remaining capacity in the battery.

A redox indicator 204 may be disposed between a bottom surface of the first atomic layer 201 and a top surface of the second atomic layer 202, as shown in FIG. 2B. Without being bound by theory a redox indicator 204 disposed between a bottom surface of the first atomic layer 201 and a top surface of the second atomic layer 202 may indicate that the battery has about 15% to about 20% remaining capacity in the battery.

A redox indicator 204 may be disposed between a bottom surface of the second atomic layer 202 and a top surface of the third atomic layer 203 as shown in FIG. 2C. Without being bound by theory a redox indicator 204 disposed between a bottom surface of the second atomic layer 202 and a top surface of the third atomic layer 203 may indicate that the battery has about 10% to about 15% remaining capacity in the battery.

A redox indicator 204 may be disposed adjacent to a bottom surface of the third atomic layer 203 as shown in FIG. 2D. Without being bound by theory a redox indicator 204 disposed adjacent to a bottom surface of the third atomic layer 203 may indicate that the battery has about 0% to about 10% remaining capacity in the battery.

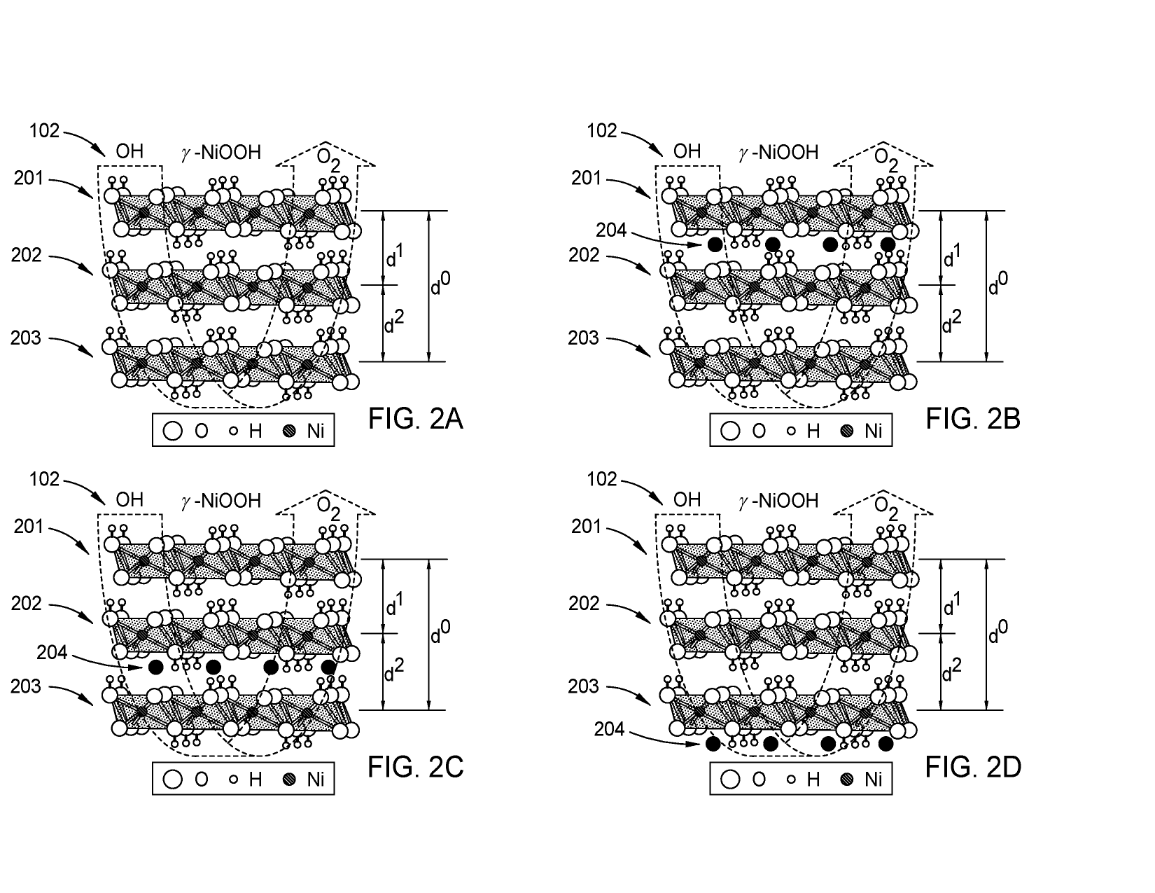

Now referring to FIG. 3, a method 300 of disposing a redox indicator in a cathode is shown. At step 301 a semi-conductive component is produced. The semi-conductive component is produced by mixing nickel acetate with oxalic acid to produce nickel oxalate. The nickel oxalate is then mixed with sodium hydroxide to produce Ni(OH)₂. Without being bound by theory, the semi-conductive component may be produced such that the semi-conductive component includes a crystalline structure. The crystalline structure may be produced such that there is a uniform d-spacing between each of the crystalline lattices within the semi-conductive component, which promotes uniform exfoliation.

At step 302, an atomic layer of the semi-conductive component is exfoliated. The term “exfoliate,” as used herein refers to delaminating a layer of a component such that the layer has a thickness of about 1 atom. In an embodiment, an atomic layer may have any suitable length or width, e.g., about 100 nm to about 3 µm, while the thickness may be about 1 atom to about 10 atoms, e.g., about 1 atom to about 3 atoms, about 2 atoms to about 4 atoms, about 3 atoms to about 5 atoms, about 4 atoms to about 6 atoms, about 5 atoms to about 7 atoms, about 6 atoms to about 8 atoms, about 7 atoms to about 9 atoms, or about 8 atoms to about 10 atoms. The atomic layer may be exfoliated from the semi-conductive component according to one or more exfoliating techniques. For example, exfoliating techniques can include sonication, heat, chemical potential, electrochemical potential, and/or mechanical force. In an embodiment, sonication may include sonicating for less than 10 minutes at a high ultrasonic amplitude, e.g., about 80 % to about 90%. In an embodiment, heating may include microwave-hydrothermal heating at short times, e.g., less than or equal to 30 seconds, and at high temperatures, e.g., greater than or equal to 150 °C. Without being bound by theory by exfoliating an atomic layer of the semi-conductive component the surface area of the semi-conductive component may increase, which reduces the distance of proton diffusion and increases power output of the cathode.

In an embodiment, the atomic layer of the semi-conductive component may be exfoliated after introducing a chemical precursor, e.g., sodium dodecyl sulfate, sodium cholate, urea, sodium metaborate tetrahydrate, alkali metals and transition-metal halides, dimethylsulphoxide (DMSO), N-methyl-pyrrolidinone (NMP), N-vinyl-Pyrrolidinone (NVP), or supercritical carbon dioxide. Without wishing to be bound by theory the chemical precursor may increase the spacing between each of the atomic layers via intercalation by using Van der Waals interactions, to promote exfoliation of the semi-conductive component.

At step 303, the cathode is produced by arranging the atomic layer of the semi-conductive component with a layer of a conductive component layer. In an embodiment, the layer of the conductive component layer may be an atomic layer of the conductive component. In an embodiment, the arrangement of the atomic layer of the semi-conductive component and the atomic layer of the conductive component may occur due to one or more of electrostatic interactions and/or steric effects. For example, a positive charge may exist in a first location of the atomic layer of the semi-conductive component, where a negative charge corresponding to a second location of the atomic layer of the conductive component may bind to the first location. In an embodiment, the arrangement may occur in one or more solvents, e.g., aqueous solvents, polar solvents, non-polar solvents, or organic solvent. The one or more solvents may be heated to a temperature of about 25 °C to about 80 °C, e.g., about 25 °C to about 30 °C, to about 30 °C to about 50 °C, about 50 °C to about 70 °C, or about 70 °C to about 80 °C. Without being bound by theory, the arrangement of the atomic layer of the semi-conductive component and the atomic layer of the conductive component allows for thicker cathodes to be formed while maintaining a conductivity suitable for proton exchange in the battery. By increasing the thickness of the cathode an increase of the energy density occurs as more charge may be stored within the battery 100.

At step 304, a redox indicator is disposed in the cathode. The redox indicator may be disposed in the cathode such that the redox indicator is disposed between a top surface of a first atomic layer and a bottom surface of a second atomic layer. The redox indicator may be disposed by one or more co-deposition synthesis reactions. For example, the redox indicator may be disposed in the cathode by adding the redox indicator in the reagents of the reaction precursors. In an embodiment, disposing the redox indicator in a first position may indicate a first remaining capacity of the battery, e.g., a remaining capacity of about 0% to about 25%, such as about 0% to about 5%, about 5% to about 10%, about 10% to about 15%, about 15% to about 20%, or about 20% to about 25%. Without being bound by theory, surface modification of a cathode of Ni(OH)₂ with trace amount of redox indicators, e.g., ferrocenium, ferrocene, and/or ferrocene derivatives, may lead to a strong electron interaction and synergistic effects of Fe-Ni heteroatoms, while maintaining the crystallographic phase of the nickel hydroxide. Moreover, 2D metal–organic frameworks (MOFs) on nickel nanosheets including ferrocene units within the MOF crystalline structure may enhance the overall electron transfer capacity of the battery.

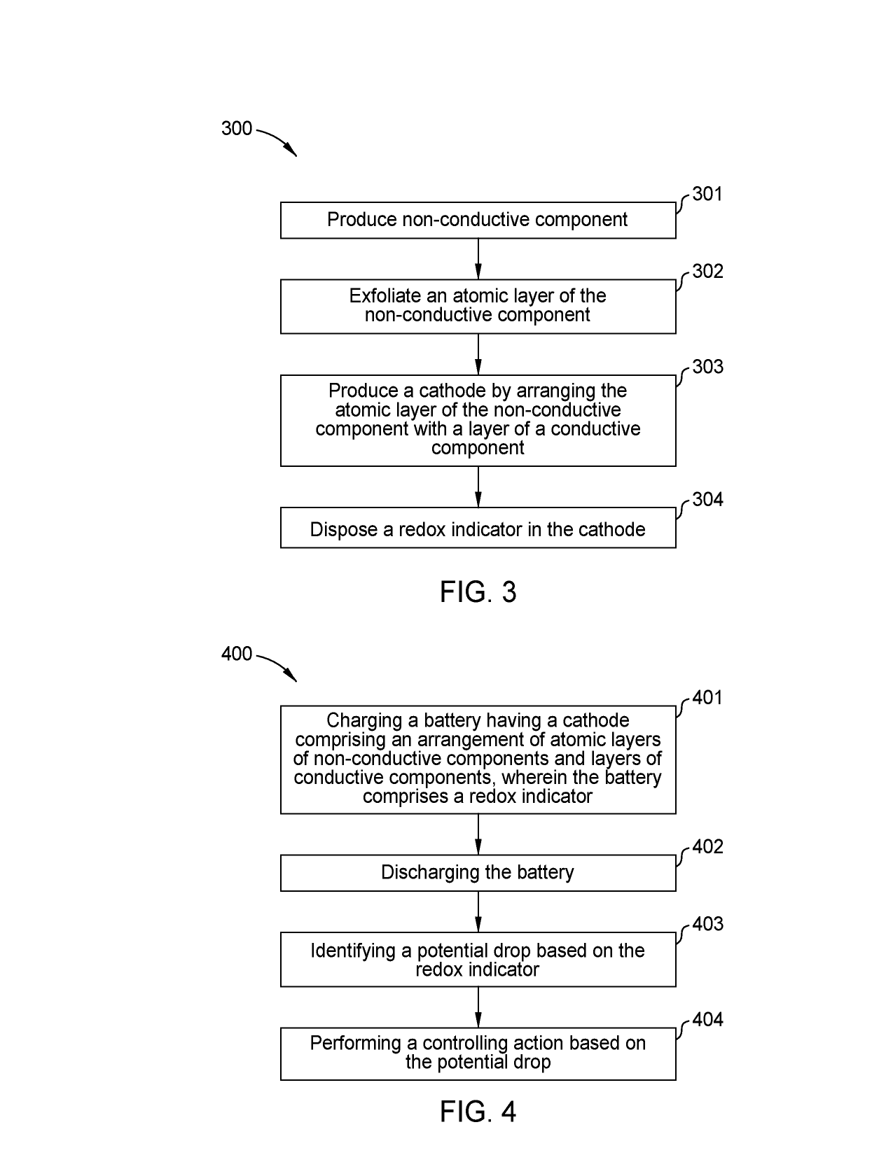

Now referring to FIG. 4, a method 400 of performing a controlling action based on a cathode having a redox indicator is shown. At step 401, a battery includes a cathode. The cathode can include a cathode porous layers and/or an arrangement of atomic layers of semi-conductive components and layers of conductive components. A redox indicator is included in the cathode. In an embodiment the battery is a metal-hydrogen battery, e.g., a H₂-Ni battery, where the total cell reaction may be 2 moles of nickel hydroxide in equilibrium with 2 moles of nickel oxyhydroxide and 1 mole of hydrogen gas. The battery may be charged by applying a potential to the battery, where nickel hydroxide is deprotonated at the cathode, e.g., a nickel electrode, converting the nickel hydroxide to nickel oxyhydroxide, water, and an electron. The water and the electron then react at the anode, e.g., a hydrogen electrode, to form hydrogen gas at the anode, which is then stored at the anode, leading to a pressure increase in the battery. In an embodiment, the charging may utilize constant current, which increases the voltage of the battery rapidly. The battery voltage may increase at a slower rate where the battery capacity approaches full charge, e.g., about 80% to about 100% charged, e.g., about 80% to about 85%, about 85% to about 90%, about 90% to about 95%, or about 95% to about 100%. In an embodiment, the H₂-Ni battery may have a reduced internal resistance, which may result in an increased voltage efficiency.

At step 402, the battery is discharged. In an embodiment, the discharge of the battery may be a quasi-flat or flat discharge profile. During discharge the anode oxidizes the hydrogen gas to produce water, which reacts with the nickel oxyhydroxide to convert the nickel oxyhydroxide to nickel hydroxide. In an embodiment, during discharge a voltage of a fully charged H₂-Ni battery may drop slowly at an initial discharge, where the voltage drops faster when the battery has a low remaining capacity, e.g., about 0% to about 20% charged, e.g., about 0% to about 5%, about 5% to about 10%, about 10% to about 15%, or about 15% to about 20%. The internal resistance of the battery may remain constant, during discharge until the battery has a remaining capacity of about 0% to about 20% charged, e.g., about 0% to about 5%, about 5% to about 10%, about 10% to about 15%, or about 15% to about 20%.

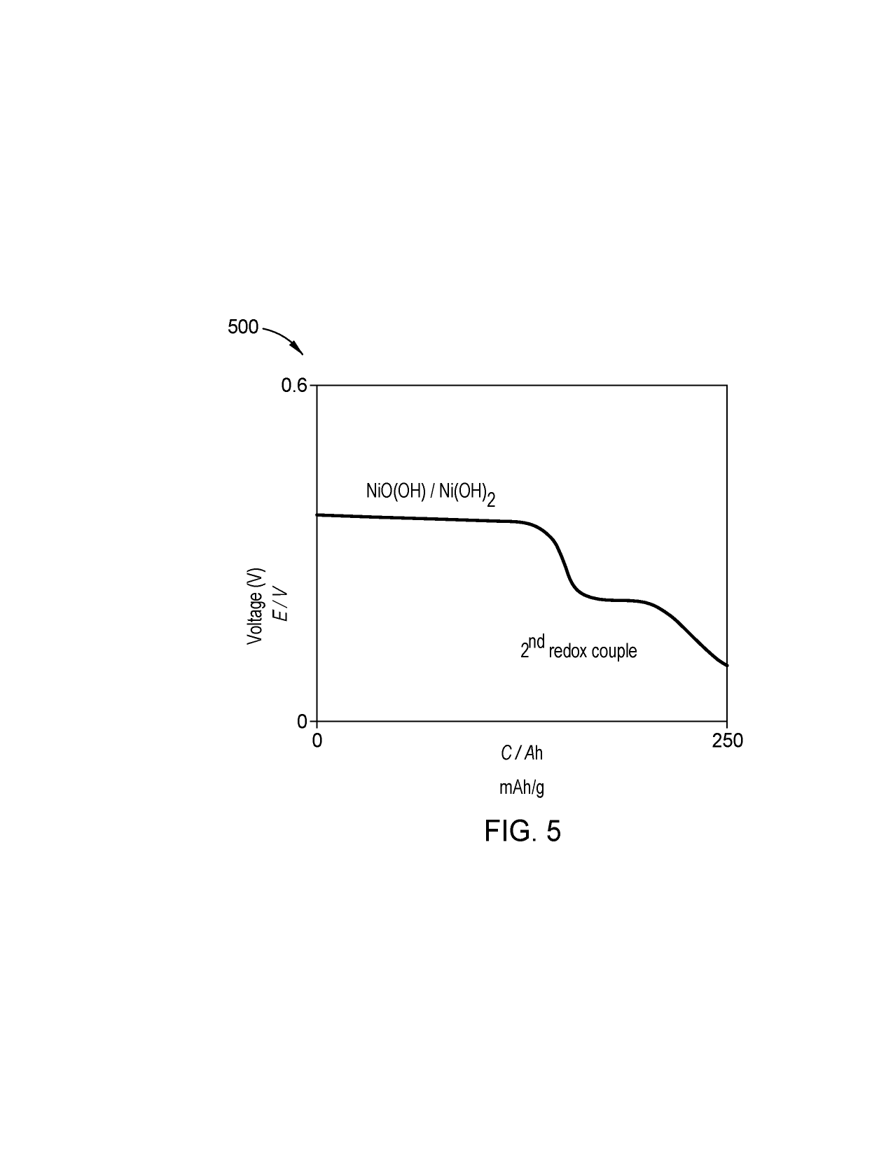

At step 403, a potential drop is identified based on the redox indicator. The potential drop may be measured by a standard hydrogen electrode, reversible hydrogen electrode, and/or normal hydrogen electrode. A potential to current graph 500 may indicate a potential drop where a second plateau of a potential drop occurs during the discharge, as shown in FIG. 5. The drop in potential may indicate that there is a remaining capacity of the battery of about 0% to about 20% charged, e.g., about 0% to about 5%, about 5% to about 10%, about 10% to about 15%, or about 15% to about 20%. In an embodiment, the drop in potential may occur at a voltage value that is less than the reversible redox potential of nickel hydroxide and/or nickel oxyhydroxide, e.g., less than about 1.4 V as measured by a reversible hydrogen electrode. Without being bound by theory, a drop in potential of the redox indicator that is less than the reversible redox potential of nickel hydroxide and/or nickel oxyhydroxide allows for a control system to accurately detect the battery capacity of the battery as the drop in potential is detectable outside of the redox potential of the nickel hydroxide and/or nickel oxyhydroxide.

Referring again to FIG. 4, at step 403, a controlling action may be performed by a control system based on the potential drop. A controlling action may include a shutdown procedure, a reduction of voltage output, a reduction of current output, a reduction of power output, an action of charging the battery, or the like. In an embodiment, the controlling action may include a system level action, such as battery balancing. Alternatively, the controlling action may include a cell level action, such as cell rebalancing, which may optimize the battery. In an embodiment, the controlling action may be performed by one or more of a computing device, microprocessor, processing board, or the like. In an embodiment, the controlling action may preserve one or more of the battery capacity. In an embodiment, the controlling action may signal an alert or other notification that the battery should be charged. Without being bound by theory, the controlling action may enhance the number of battery cycles capable by signaling an optimal charging point for the battery. Additionally, and without being bound by theory, the controlling action may reduce an amount of overcharging. The controlling action may also indicate a current battery capacity to a user, increasing the estimation of a current battery remaining capacity such that the battery is prevented from depletion and/or overcharging.

Overall, the present disclosure relates to methods of monitoring a battery state of charge using a redox indicator. A redox indicator permits a state of charge to be determined by implementing a second drop in potential within the discharge profile. The second drop in potential may indicate one or more remaining capacities of the battery. This allows for batteries that follow a flat discharge profile, e.g., batteries including cathodes such as Ni, LiFePO₄, LiMnO₂, to have their residual capacity monitored. Additionally, the redox indicator may also allow for enhanced electron transfer capacity of the battery due to the strong electron interaction and synergistic effects of the redox indicator with the cathode of the battery.

The phrases, unless otherwise specified, "consists essentially of" and "consisting essentially of" do not exclude the presence of other steps, elements, or materials, whether or not, specifically mentioned in this specification, so long as such steps, elements, or materials, do not affect the basic and novel characteristics of the present disclosure, additionally, they do not exclude impurities and variances normally associated with the elements and materials used.

Numerical ranges used herein include the numbers recited in the range. For example, the numerical range “from 1 wt % to 10 wt %” includes 1 wt % and 10 wt % within the recited range.

For the sake of brevity, only some ranges are explicitly disclosed herein. However, ranges from any lower limit may be combined with any upper limit to recite a range not explicitly recited, as well as, ranges from any lower limit may be combined with any other lower limit to recite a range not explicitly recited, in the same way, ranges from any upper limit may be combined with any other upper limit to recite a range not explicitly recited. Additionally, within a range includes every point or individual value between its end points even though not explicitly recited. Thus, every point or individual value may serve as its own lower or upper limit combined with any other point or individual value or any other lower or upper limit, to recite a range not explicitly recited.

All numerical values within the detailed description herein are modified by “about” the indicated value, and consider experimental error and variations that would be expected by a person having ordinary skill in the art.

All documents described herein are incorporated by reference herein, including any priority documents and or testing procedures to the extent they are not inconsistent with this text. As is apparent from the foregoing general description and the specific embodiments, while forms of the present disclosure have been illustrated and described, various modifications can be made without departing from the spirit and scope of the present disclosure. Accordingly, it is not intended that the present disclosure be limited thereby. Likewise, the term “comprising” is considered synonymous with the term “including” for purposes of United States law. Likewise whenever a composition, an element or a group of elements is preceded with the transitional phrase “comprising,” it is understood that we also contemplate the same composition or group of elements with transitional phrases “consisting essentially of,” “consisting of,” “selected from the group of consisting of,” or “is” preceding the recitation of the composition, element, or elements and vice versa.

The specific embodiments described herein have been illustrated by way of example, and it should be understood that these embodiments may be susceptible to various modifications and alternative forms. It should be further understood that the claims are not intended to be limited to the particular forms disclosed, but rather to cover all modifications, equivalents, and alternatives falling within the spirit and scope of this disclosure.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for (perform)ing (a function)…” or “step for (perform)ing (a function)…”, it is intended that such elements are to be interpreted under 35 U.S.C. 112(f). However, for any claims containing elements designated in any other manner, it is intended that such elements are not to be interpreted under 35 U.S.C. 112(f).

While the present disclosure has been described with respect to a number of embodiments and examples, those skilled in the art, having benefit of this disclosure, will appreciate that other embodiments can be devised which do not depart from the scope and spirit of the present disclosure.

What is claimed is:

1. An apparatus, the apparatus comprising:
a cathode comprising a redox indicator, wherein the redox indicator is selected from the group consisting of an organic compound, an organometallic compound, and a transition metal oxide; and an anode.

2. The apparatus of claim 1, wherein the redox indicator is an organic compound selected from the group consisting of quinone, benzoquinone, and quinone derivatives.

3. The apparatus of claim 1, wherein the redox indicator is an organometallic compound selected from the group consisting of ferrocenium, ferrocene, and ferrocene derivatives.

4. The apparatus of claim 1, wherein the redox indicator is a transition metal oxide selected from the group consisting of Fe₂O₃ CuO, ZnO, and/or MnO_{2.}

5. The apparatus of claim 1, wherein the redox indicator is ferrocene, cobaltocene, tri(triphenylphosphine)rhodium carbonyl hydride, Zeise’s salt, trimethylaluminum, dimethylzinc, lithium diphenylcuprate bi(diethyl ethereate), adenosylcobalamin, iron pentacarbonyl, trimethylboron, trimethyl silicon, thianthrene, iron(II) tris-bipyridine, decamethylferrocene, oxaphosphirane complexes, ferrocenium salts, silver(I) salts, copper(II) halide, copper(I) salts, trications, benzoquinone derivatives, benzoquinone polymers, (poly)(2,2,6,6-Tetramethylpiperidin-1-yl)oxyl “(poly)TEMPO”, or technetium sestamibi.

6. The apparatus of claim 1, wherein the redox indicator comprises a reversible redox behavior having a redox potential of about 0.1 V to about 1.5 V.

7. The apparatus of claim 1, wherein the redox indicator comprises a reversible redox behavior having a redox potential of about 0.1 V to about 1.4 V.

8. The apparatus of claim 1, wherein the anode comprises one or more anode porous layers.

9. The apparatus of claim 8, wherein each of the anode porous layers comprises a porous conductive substrate coated with a catalyst layer.

10. A method of performing a controlling action, the method comprising:
charging a battery having a cathode comprising a redox indicator;
discharging the battery, wherein discharging the battery comprises:
identifying a potential drop of the redox indicator; and
performing the controlling action based on the potential drop.

11. The method of claim 10, wherein charging the battery comprises deprotonating a nickel hydroxide at a cathode electrode to form a nickel oxyhydroxide.

12. The method of claim 11, wherein charging the battery comprises producing a hydrogen gas at an anode electrode.

13. The method of claim 12, wherein discharging the battery comprises protonating the nickel oxyhydroxide using the hydrogen gas to produce the nickel hydroxide.

14. The method of claim 12, wherein the anode electrode comprises one or more anode porous layers.

15. The method of claim 10, wherein the redox indicator is selected from the group consisting of an organic compound, an organometallic compound, and a transition metal oxide.

16. The method of claim 15, wherein the redox indicator is an organic compound selected from the group consisting of quinone, benzoquinone, and quinone derivatives.

17. The method of claim 15, wherein the redox indicator is an organometallic compound selected from the group consisting of ferrocenium, ferrocene, and ferrocene derivatives.

18. The method of claim 15, wherein the redox indicator is a transition metal oxide selected from the group consisting of Fe₂O₃ CuO, ZnO, and/or MnO_{2.}

19. The method of claim 10, wherein the redox indicator comprises a reversible redox behavior having a redox potential of about 0.1 V to about 1.5 V.

20. The method of claim 19, wherein the redox indicator comprises a reversible redox behavior having a redox potential of about 0.1 V to about 1.4 V.
